(19) United States
(12) Patent Application Publication
(10) Pub. No.: US 2024/0426882 A1
(43) Pub. Date: Dec. 26, 2024

(54) PULSE COUNTER

(71) Applicant: DOLPHIN DESIGN, MEYLAN (FR)

(72) Inventors: Konan Constant ESSEY, MEYLAN (FR); Gaspard TRICAUD, MEYLAN (FR)

(21) Appl. No.: 18/743,314

(22) Filed: Jun. 14, 2024

(30) Foreign Application Priority Data
Jun. 22, 2023 (FR) 2306509

(51) Int. Cl. G01R 23/10; G06F 1/12

(52) U.S. Cl. CPC G01R 23/10; G06F 1/12

(57) ABSTRACT

The present description relates to a pulse counter (200) comprising an asynchronous counter (201) and a circuit (205) configured to trigger a read operation of the value of said asynchronous counter, said circuit (205) being synchronized by a clock signal.

This application claims the priority benefit of French patent application number FR2306509, filed on Jun. 22, 2023, entitled “Compteur d'impulsions”, which is hereby incorporated by reference to the maximum extent allowable by law.

### TECHNICAL FIELD

The present description relates generally to electronic circuits and devices used in the field of audio file processing. The present description relates more particularly to a circuit for counting pulses of a signal obtained from an audio file.

### BACKGROUND ART

Audio file processing, and in particular the processing of audio files representing the human voice, is an important issue in many scientific fields.

It would be desirable to be able to improve, at least in part, certain aspects of the circuits and devices used in the field of audio file processing, and, in particular, certain aspects of the circuits for counting pulses of a signal obtained from an audio file.

### SUMMARY OF INVENTION

There is a need for more efficient circuits and devices used in audio file processing.

There is a need for low-frequency circuits and devices used in audio file processing.

There is a need for more powerful circuits to count pulses in a signal obtained from an audio file.

There is a need for circuits that can count pulses from a signal obtained from an audio file and operate on a frequency basis.

One embodiment overcomes some or all of the drawbacks of known circuits and devices used in audio file processing.

One embodiment overcomes some or all of the drawbacks of known circuits for counting pulses in a signal obtained from an audio file.

One embodiment provides a pulse counter comprising an asynchronous counter and a circuit configured to trigger a read operation of the value of said asynchronous counter, said circuit being synchronized by a clock signal.

According to one embodiment, the counter further comprises a flip-flop adapted to receive said value of said asynchronous counter during a reading phase.

In one embodiment, a reading phase is triggered by an edge of a first synchronization signal.

In one embodiment, a reading phase is stopped by an edge of a second synchronization signal.

According to an embodiment, said edge of the second synchronization signal also triggers a reset of said asynchronous counter value.

Another embodiment provides a circuit suitable for recognizing words from an audio file, comprising a pulse counter previously described.

In one embodiment, the circuit has a clock frequency of between 30 and 40 KHz.

In one embodiment, the clock frequency is 32.728 kHz.

According to one embodiment, the circuit further comprises a first circuit adapted to implement an acoustic characteristic extraction function.

In one embodiment, the circuit also comprises a second circuit adapted to integrate a signal supplied by the first circuit.

According to one embodiment, the circuit further comprises a third circuit configured to implement digital processing of a signal supplied by said pulse counter.

Another embodiment provides a device adapted to process file comprising a circuit previously described.

In one embodiment, the device also includes a microphone.

In one embodiment, the device also comprises a neural network.

In one embodiment, the device is adapted to detect the human voice.

### BRIEF DESCRIPTION OF THE DRAWINGS

These and other features and advantages will be set out in detail in the following non-limiting description of particular embodiments in relation to the accompanying figures, which include:

FIG. 1 shows, very schematically and in the form of blocks, an example of a device for processing an audio file;

FIG. 2 shows a circuit diagram of a pulse counter of the type shown in FIG. 1; and

FIG. 3 shows chronograms illustrating the operation of FIG. 2.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

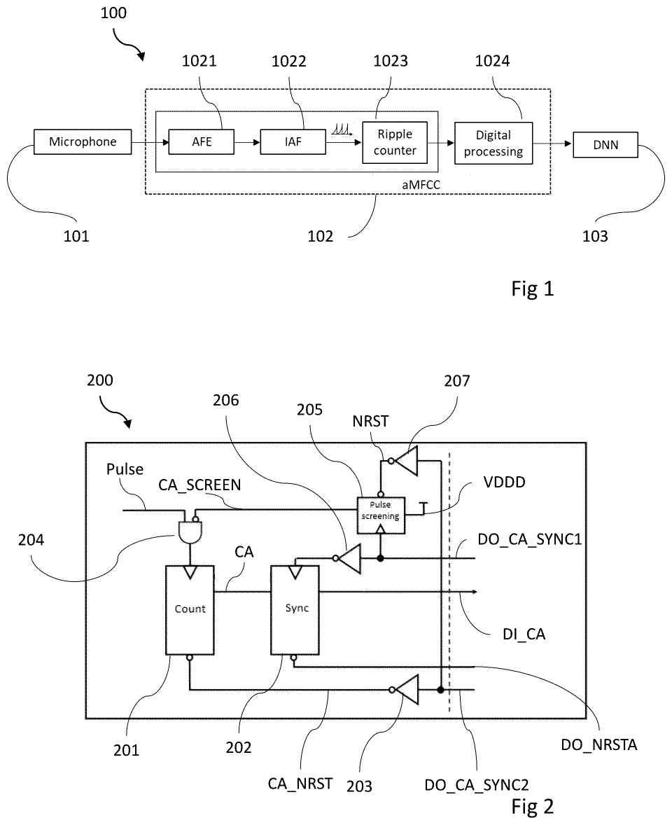

FIG. 1 shows a block diagram of a device 100 for processing an audio file.

According to one embodiment, device 100 is adapted to acquire an audio file and then process it. To this end, and according to one example, the device 100 comprises:
a microphone 101 (Microphone);
a circuit 102 (aMFCC) adapted to recognize certain audio data; and
a neural network 103 (DNN).

According to a preferred embodiment, device 100 is adapted to acquire and process an audio file comprising a human voice. More particularly, the device 100 is adapted to detect the human voice.

According to one example, microphone 101 is an electronic device adapted to acquire an audio file. Microphone 101 is configured to provide a raw audio file.

According to one example, circuit 102 is adapted to recognize certain audio data from the raw audio file supplied by microphone 101. In the preferred embodiment, circuit 102 is adapted for word recognition.

According to one example, circuit 102 comprises:
a circuit 1021 (AFE) adapted to implement a function for extracting an acoustic characteristic;
a circuit 1022 (IAF) adapted to filter an acoustic characteristic extracted by circuit 1021;
a pulse counter 1023 (Ripple Counter) according to one embodiment; and
a circuit 1024 (Digital processing) configured to implement digital processing of a signal supplied by said pulse counter 1023.

According to one example, circuit 1021 (AFE) is adapted to extract an acoustic characteristic from the raw audio file provided by microphone 101. More specifically, circuit 1021 is adapted to extract certain properties from the raw audio file it receives from microphone 101.

According to one example, circuit 1022 (IAF) is adapted to filter an acoustic characteristic extracted by circuit 1021, and more particularly to integrate a signal supplied by circuit 1021. Circuit 1022 supplies a signal comprising pulses to counter 1023. According to one example, circuit 1022 is an analog-to-digital converter driven by a software event.

According to one embodiment, the pulse counter 1023 is an asynchronous counter operating in the analog domain of the circuit 102, and is adapted to count the number of pulses of the signal supplied by the circuit 1022 during a given duration. This given duration generally corresponds to a calculation window defined by the duration of the raw audio file acquired by microphone 101.

According to one embodiment, circuits 1021 and 1022 and counter 1023 are all part of the analog domain of circuit 102, and are all adapted to operate at low frequency, that is at a frequency of between 30 and 40 kHz, for example of the order of 32.726 kHz.

According to one example, circuit 1024 is configured to implement digital processing of a signal supplied by said pulse counter 1023. The circuit 1024 is part of a digital domain of the circuit 102.

According to one example, neural network 103 is adapted to receive data from circuit 1024 and to process it. According to one example, neural network 103 is a deep neural network.

FIG. 2 is a circuit diagram of a pulse counter 200 of the type of pulse counter 1023 described in relation to FIG. 1.

Pulse counter 200 is a pulse counter adapted to operate at low frequency. To this end, the pulse counter is adapted to count pulses asynchronously, and is adapted to provide the result of its count synchronously, that is synchronized with a clock signal.

According to one embodiment, the pulse counter 200 comprises an asynchronous counter circuit 201 (Count) comprising an input terminal, an output terminal supplying an AC signal, and an inverting reset terminal receiving a CA_NRST reset signal.

The pulse counter 200 also includes, for example, a flip-flop 202 (Sync) for reading the value of the asynchronous counter 201. The flip-flop 202 comprises an input terminal receiving the AC signal from the asynchronous counter 201, and an output terminal providing an output signal DI_CA from the pulse counter 200. The DI_CA signal represents the value of the pulse counter during a reading phase. The flip-flop 202 further comprises an enable terminal, and an inverting reset terminal receiving a reset signal DO_NRSTA.

The pulse counter 200 also includes an inverter circuit 203 which receives a synchronization signal DO_CA_SYNC2 as input, and whose output is connected, preferably connected, to the reset terminal of the asynchronous counter 201. Thus, a rising edge of the DO_CA_SYNC2 synchronization signal resets the value of the asynchronous counter 201 to an initial value, for example zero.

The pulse counter 200 also includes an AND logic gate 204 comprising a first input terminal receiving a pulse signal to be analyzed, and a second inverting input terminal receiving a CA_SCREEN signal. An output terminal of gate 204 is linked, preferably connected, to the input terminal of asynchronous counter 201.

According to one embodiment, the pulse counter 200 further comprises a circuit 205 (Pulse Screen) configured to trigger a pulse counter read operation. Circuit 205 comprises:
a supply terminal receiving a supply voltage VDDD;
an inverting reset terminal;
an input terminal receiving a DO_CA_SYNC1 synchronization signal; and
an output terminal supplying the CA_SCREEN signal.

The pulse counter 200 also includes an inverter circuit 206 which receives the DO_CA_SYNC1 synchronization signal as input, and whose output is connected, preferably connected, to the input terminal of the flip-flop 202.

The pulse counter 200 also includes an inverter circuit 207 which receives the DO_CA_SYNC2 synchronization signal as input, and whose output is connected, preferably connected, to the inverting reset terminal of circuit 205.

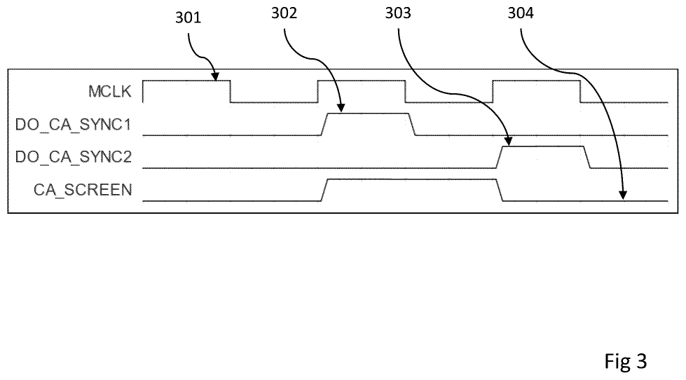

Pulse counter 200 operates as follows. The asynchronous counter 201 counts the pulses present on the signal as long as the CA_SCREEN signal is in a low state. A reading phase only takes place when the CA_SCREEN signal is in a high state. The implementation of a phase for reading the value of the asynchronous counter 201 is described in relation to FIG. 3.

FIG. 3 shows four chronograms 301, 302, 303 and 304, illustrating the operation of the design shown in FIG. 2.

More specifically, FIG. 3 comprises:
a chronogram 301 representing the time evolution of a clock signal MCLK;
a chronogram 302 representing the temporal evolution of the DO_CA_SYNC1 synchronization signal;
a chronogram 303 representing the temporal evolution of the DO_CA_SYNC1 synchronization signal;
a chronogram 303 representing the time evolution of the DO_CA_SYNC2 synchronization signal; and
a chronogram 304 representing the time evolution of the CA_SCREEN signal.

The clock signal MCLK is used to synchronize the reading phases of the asynchronous counter 201, and the synchronization signals DO_CA_SYNC1 and DO_CA_SYNC2. According to one example, the clock signal is low-frequency, that is at a frequency of between 30 and 40 kHz, for example of the order of 32.726 KHz.

As mentioned previously, a reading phase is implemented when the CA_SCREEN signal is in a high state.

A rising edge of the CA_SCREEN signal is triggered by a rising edge of the DO_CA_SYNC1 synchronization signal, which in turn is triggered by a rising edge of the MCLK clock signal.

In addition, a rising edge of the DO_CA_SYNC1 synchronization signal deactivates the 202 flip-flop, and thus fixes the data it stores. This data corresponds to the value of the asynchronous counter 201. A falling edge of the DO_CA_SYNC1 synchronization signal is triggered by a falling edge of the MCLK clock signal. The falling edge of the synchronization signal triggers the reading of asynchronous counter 201.

A falling edge of the CA_SCREEN signal is triggered by a rising edge of the DO_CA_SYNC2 synchronization signal. This rising edge of the DO_CA_SYNC2 synchronization signal also enables the asynchronous counter 201 to be resetted.

One advantage of this type of pulse counter is that it can be implemented by a circuit operating at low frequency, even if the frequency of the received pulses is higher than this low frequency. In particular, this pulse counter can be integrated into a low-power, always-on part of an electronic device, commonly referred to as the ALWAYS ON part.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A pulse counter comprising an asynchronous counter and a circuit configured to trigger a read operation of the value of said asynchronous counter, said circuit being synchronized by a clock signal.

2. Counter according to claim 1, further comprising a flip-flop adapted to receive said value from said asynchronous counter during a reading phase.

3. Counter according to claim 1, in which a reading phase is triggered by an edge of a first synchronization signal.

4. Counter according to claim 1, in which a reading phase is stopped by an edge of a second synchronization signal.

5. Counter according to claim 4, wherein said edge of the second synchronization signal further triggers the resetting of said value of said asynchronous counter.

6. A circuit suitable for recognizing words from an audio file comprising a pulse counter according to claim 1.

7. Circuit according to claim 6, having a clock frequency between 30 and 40 kHz.

8. Circuit according to claim 7, in which the clock frequency is equal to 32.728 kHz.

9. A circuit according to claim 6, further comprising a first circuit adapted to implement an acoustic characteristic extraction function.

10. A circuit according to claim 6, further comprising a second circuit adapted to integrate a signal supplied by the first circuit.

11. A circuit according to claim 6, further comprising a third circuit configured to implement digital processing of a signal supplied by said pulse counter.

12. A device adapted to process an audio file comprising a circuit according to claim 6.

13. Device according to claim 12, further comprising a microphone.

14. Device according to claim 12, further comprising a neural network.

15. Device according to claim 12, adapted to detect the human voice.
